(19) United States
(12) Patent Application Publication
(10) Pub. No.: US 2021/0357566 A1
(43) Pub. Date: Nov. 18, 2021

(54) METHODS FOR GENERATING CHARACTERISTIC PATTERN AND TRAINING MACHINE LEARNING MODEL

(71) Applicant: ASML NETHERLAND B.V., Veldhoven (NL)

(72) Inventors: Mark Christopher SIMMONS, Santa Clara, CA (US); Chenxi LIN, Newark, CA (US); Jen-Yi WUU, Sannyvale, CA (US)

(73) Assignee: ASML NETHERLAND B.V., Veldhoven (NL)

(21) Appl. No.: 17/281,123

(22) PCT Filed: Oct. 8, 2019
(86) PCT No.: PCT/EP2019/077146

§ 371 Date: Mar. 29, 2021

Related U.S. Application Data
(60) Provisional application No. 62/746,784, filed on Oct. 17, 2018.

(51) Int. Cl. G06F 30/392; G03F 7/20; G06N 3/08; G06N 3/04

(52) U.S. Cl. CPC G06F 30/392; G03F 7/70525; G06N 3/0454; G06N 3/08; G03F 7/705

(57) ABSTRACT

A method of generating a characteristic pattern for a patterning process and training a machine learning model. The method for generating the characteristic pattern includes obtaining a trained generator model configured to generate a characteristic pattern (e.g., a hot spot pattern), and an input pattern; and generating, via simulation using the trained generator model (e.g., CNN), the characteristic pattern based on the input pattern, wherein the input pattern can be a random vector and/or a class of pattern.

### CROSS-REFERENCE TO RELATED APPLICATIONS

This application claims priority of U.S. application 62/746,784 which was filed on Oct. 17, 2018 and which is incorporated herein in its entirety by reference.

### TECHNICAL FIELD

The description herein relates generally to apparatus and methods of a patterning process and determining characteristic patterns corresponding to a design layout.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

According to an embodiment, there is provided a method of generating a characteristic pattern for a patterning process. The method includes obtaining a trained generator model configured to generate a characteristic pattern, and an input pattern; and generating, via simulation of the trained generator model, the characteristic pattern based on the input pattern, wherein the input pattern is at least one of a random vector or a class of pattern.

In an embodiment, the characteristic pattern is a patterning device pattern to be printed on a substrate subjected to the patterning process.

In an embodiment, the input pattern is obtained via simulation of a process model of the patterning process with a design layout as an input that results in the hotspot pattern.

In an embodiment, the process model comprises an optical proximity correction model and a lithographic manufacturability check model.

In an embodiment, the method further includes converting the characteristic pattern to a characteristic contour representation; applying a design rule check to the characteristic contour representation; and modifying the characteristic contour representation based on the design rule check to increase a likelihood that the characteristic pattern are printable.

In an embodiment, the converting the characteristic pattern comprises extracting contours of features within the characteristic pattern; and converting the contours to geometric shapes and/or Manhattanize the characteristic pattern.

In an embodiment, the method further comprising: determining via simulation of the optical proximity correction model, optical proximity corrections for the modified characteristic contour; determining, via simulation of the process model of the patterning process, a simulated pattern of the substrate corresponding to the modified characteristic contour.

In an embodiment, the method further comprising: determining, via simulation of the process model of the patterning process, settings of the patterning process based on the characteristic pattern and/or the modified characteristic contour.

In an embodiment, the settings of the patterning process are values of the process variables including dose, focus, and/or optical parameters.

In an embodiment, the method further comprising: printing, via the lithographic apparatus, the characteristic pattern on the substrate applying the settings of the patterning process.

In an embodiment, the trained generator model is a convolution neural network.

In an embodiment, the trained generator model is trained according to a machine learning training method called a generative adversarial network.

In an embodiment, the characteristic pattern and the input pattern is a pixelated image.

In an embodiment, the input pattern includes a design layout including a hotspot pattern.

Furthermore, the present disclosure provides a method of training a machine learning model for generating a characteristic pattern of a patterning process. The method includes obtaining a machine learning model comprising (i) a generator model configured to generate a characteristic pattern to be printed on a substrate subjected a patterning process, and (ii) a discriminator model configured to distinguish the characteristic pattern from a training pattern; and training, via a computer hardware system, the generator model and the discriminator model in a cooperative manner other based on a training set comprising the training pattern, such that the generator model generates the characteristic pattern that matches the training pattern and the discriminator model identifies the characteristic pattern as the training pattern, wherein the characteristic pattern and the training pattern comprises a hotspot pattern.

In an embodiment, the training is an iterative process, an iteration comprises: generating the characteristic pattern, via simulation of the generator model with an input vector; evaluating a first cost function related to the generator model; distinguishing, via the discriminator model, the characteristic pattern from the training pattern; evaluating a second cost function related to the discriminator model; and adjusting parameters of the generator model to improve the first cost function, and parameters of the discriminator model to improve the second cost function.

In an embodiment, the input vector is a random vector and/or a seed hotspot image.

In an embodiment, the seed hotspot image is obtained from simulation of lithographic process with a design layout as an input.

In an embodiment, the distinguishing comprises: determining a probability that the characteristic pattern is the training pattern; and responsive to the probability, assigning a label to the characteristic pattern, the label indicates whether the characteristic pattern is as a real pattern or a fake pattern.

In an embodiment, responsive to the probability breaching a threshold value, the characteristic pattern is labelled as a real pattern.

In an embodiment, the first cost function comprises a first log-likelihood term that determines a probability that the characteristic pattern is a fake given the input vector.

In an embodiment, the adjusting of parameters of the generator model is such that the first log-likelihood term is minimized.

In an embodiment, the second cost function includes a second log-likelihood term that determines a probability that the characteristic pattern is real given the training pattern.

In an embodiment, the adjusting of the second model parameters is such that the second log-likelihood term is maximized.

In an embodiment, the training pattern includes a hotspot pattern.

In an embodiment, the training pattern is obtained from simulation of a process model of the patterning process, metrology data of a printed substrate, and/or a database storing printed patterns.

In an embodiment, the characteristic pattern includes features resembling the training pattern;

In an embodiment, the characteristic pattern and the training pattern further comprises a non-hotspot pattern, and/or a user-defined pattern.

In an embodiment, the method further comprising generating, via simulation of the trained generator model, a design pattern including a hotspot pattern and/or a user-defined pattern.

In an embodiment, the generator model and the discriminator model are convolution neural networks.

### BRIEF DESCRIPTION OF THE DRAWINGS

The above aspects and other aspects and features will become apparent to those ordinarily skilled in the art upon review of the following description of specific embodiments in conjunction with the accompanying figures, wherein:

FIG. 1 shows a block diagram of various subsystems of a lithography system, according to an embodiment;

FIG. 2 shows example categories of the processing variables, according to an embodiment;

FIG. 3 is a flow chart for modelling and/or simulating parts of a patterning process, according to an embodiment;

FIG. 4 shows a flow chart for a method of determining existence of defects in a lithography process, according to an embodiment;

FIG. 5 is an overview of a machine learning based hot spot pattern generation method, according to an embodiment;

FIG. 6 is a flow chart of a method of generating a characteristic pattern for a patterning process, according to an embodiment;

FIG. 7 illustrates an overview of a training process of a machine learning model based on generative adversarial network architecture, according to an embodiment;

FIG. 8 is a flow chart of an example method of training a generator model of FIG. 6, according to an embodiment;

FIG. 9A is an example of a real pattern printed on a substrate, according to an embodiment;

FIG. 9B is an example of a characteristic pattern corresponding to the FIG. 9A generated by the trained generator model of FIG. 7, according to an embodiment;

FIG. 10 illustrates example defects and example ways to tackle the defects, according to an embodiment;

FIG. 11 is a block diagram of an example computer system, according to an embodiment;

FIG. 12 is a schematic diagram of a lithographic projection apparatus, according to an embodiment;

FIG. 13 is a schematic diagram of another lithographic projection apparatus, according to an embodiment;

FIG. 14 is a more detailed view of the apparatus in FIG. 12, according to an embodiment;

FIG. 15 is a more detailed view of the source collector module SO of the apparatus of FIG. 13 and FIG. 14, according to an embodiment.

### DETAILED DESCRIPTION

Before describing embodiments in detail, it is instructive to present an example environment in which embodiments may be implemented.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The pattern layout design may include, as an example, application of resolution enhancement techniques, such as optical proximity corrections (OPC). OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, the term “mask,” “patterning device” and “design layout” can be used interchangeably, as in the context of RET, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another or non-geometrical optical effects such as diffraction and interference. Similarly, proximity effects may arise from diffusion and other chemical effects during post-exposure bake (PEB), resist development, and etching that generally follow lithography.

In order to increase the chance that the projected image of the design layout is in accordance with requirements of a given target circuit design, proximity effects may be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

An assist feature may be viewed as a difference between features on a patterning device and features in the design layout. The terms “main feature” and “assist feature” do not imply that a particular feature on a patterning device must be labeled as one or the other.

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

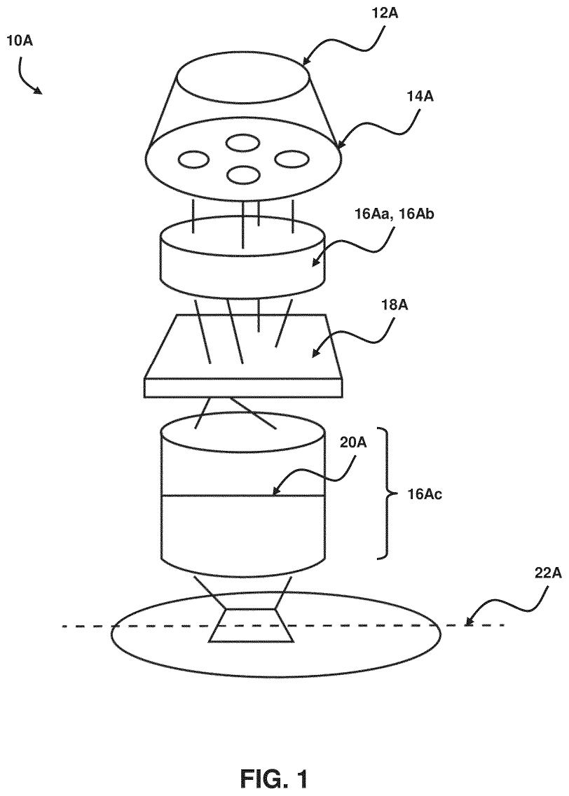

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(θₘₐₓ), wherein n is the refractive index of the media between the substrate and the last element of the projection optics, and θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it may be desirable to separate the optical properties of the patterning device from the optical properties of the rest of the lithographic projection apparatus including at least the source and the projection optics.

Although specific reference may be made in this text to the use of lithography apparatus in the manufacture of ICs, it should be understood that the lithography apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of all the patterns on a patterning device or an area thereof may be obtained by merging (e.g., overlapping) process windows of each individual pattern. The boundary of the process window of all the patterns contains boundaries of process windows of some of the individual patterns. In other words, these individual patterns limit the process window of all the patterns. These patterns can be referred to as “hot spots” or “process window limiting patterns (PWLPs),” which are used interchangeably herein. When controlling a part of a patterning process, it is possible and economical to focus on the hot spots. When the hot spots are not defective, it is most likely that all the patterns are not defective.

In an embodiment, simulation based approaches have been developed to verify the correctness of the design and mask layout before the mask is fabricated. One such approach is described in U.S. Pat. No. 7,003,758, entitled “System and Method for Lithography Simulation,” the subject matter of which is hereby incorporated by reference in its entirety and is referred to herein as “the simulation system.” Even with the best possible RET implementation and verification, it is still not possible to optimize every feature of a design. Some structures will often not be properly corrected due to limitations of the technology, implementation errors, or conflicts with neighboring features. The simulation system can identify specific features of the design that will result in unacceptably small process windows or excessive critical dimension (CD) variation within the normally expected range of process conditions, such as focus and exposure variation. These defective regions must be corrected before the mask is made. However, even in the best designs, there will be structures or parts of structures that cannot be optimally corrected. Although these weak areas can produce good chips, they may have marginally acceptable process windows and are likely to be the first locations within the device that will fail under varying process conditions, either due to variations of the wafer processing conditions, the mask processing conditions, or a combination of both. These weak areas are referred to herein as “hot spots.”

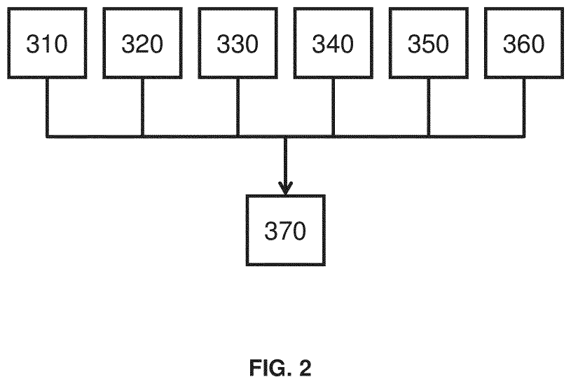

Variables of a patterning process are called “processing variables.” The term processing variables may also be interchangeably referred as “parameters of the patterning process” or “processing parameters.” The patterning process may include processes upstream and downstream to the actual transfer of the pattern in a lithography apparatus. FIG. 2 shows example categories of the processing variables 370. The first category may be variables 310 of the lithography apparatus or any other apparatuses used in the lithography process. Examples of this category include variables of the illumination, projection system, substrate stage, etc. of a lithography apparatus. The second category may be variables 320 of one or more procedures performed in the patterning process. Examples of this category include focus control or focus measurement, dose control or dose measurement, bandwidth, exposure duration, development temperature, chemical composition used in development, etc. The third category may be variables 330 of the design layout and its implementation in, or using, a patterning device. Examples of this category may include shapes and/or locations of assist features, adjustments applied by a resolution enhancement technique (RET), CD of mask features, etc. The fourth category may be variables 340 of the substrate. Examples include characteristics of structures under a resist layer, chemical composition and/or physical dimension of the resist layer, etc. The fifth category may be characteristics 350 of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). The sixth category may be characteristics 360 of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

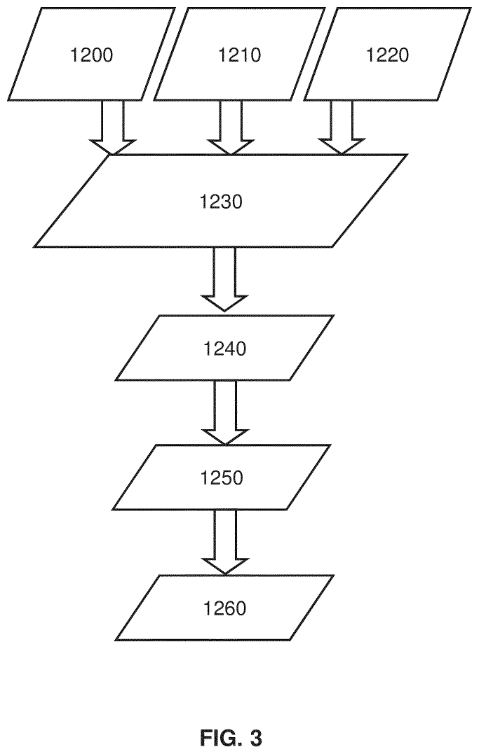

An exemplary flow chart for modelling and/or simulating parts of a patterning process is illustrated in FIG. 3. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (σ) settings as well as any particular illumination shape (e.g. off-axis radiation shape such as annular, quadrupole, dipole, etc.), where (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

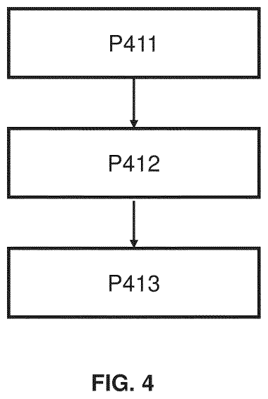

FIG. 4 shows a flow chart for a method of determining existence of defects in a lithography process, according to an embodiment. In process P411, hot spots or locations thereof are identified using any suitable method from patterns (e.g., patterns on a patterning device). For example, hot spots may be identified by analyzing patterns on patterns using an empirical model or a computational model. In an empirical model, images (e.g., resist image, optical image, etch image) of the patterns are not simulated; instead, the empirical model predicts defects or probability of defects based on correlations between processing parameters, parameters of the patterns, and the defects. For example, an empirical model may be a classification model or a database of patterns prone to defects. In a computational model, a portion or a characteristic of the images is calculated or simulated, and defects are identified based on the portion or the characteristic. For example, a line pull back defect may be identified by finding a line end too far away from its desired location; a bridging defect may be identified by finding a location where two lines undesirably join; an overlapping defect may be identified by finding two features on separate layers undesirably overlap or undesirably not overlap. An empirical model is usually less computationally expensive than a computational model. It is possible to determine and/or compile process windows of the hot spots into a map, based on hotspot locations and process windows of individual hot spots—i.e. determine process windows as a function of location. This process window map may characterize the layout-specific sensitivities and processing margins of the patterns. In another example, the hot spots, their locations, and/or their process windows may be determined experimentally, such as by FEM wafer inspection or a suitable metrology tool. The defects may include those defects that cannot be detected in an after-development-inspection (ADI) (usually optical inspection), such as resist top loss, resist undercut, etc. Conventional inspection only reveals such defects after the substrate is irreversibly processed (e.g., etched), at which point the wafer cannot be reworked. So, such resist top loss defects cannot be detected using the current optical technology at the time of drafting this document. However, simulation may be used to determine where resist top loss may occur and what the severity would be. Based on this information, it may be either decided to inspect the specific possible defect using a more accurate inspection method (and typically more time consuming) to determine whether the defect needs rework, or it may be decided to rework the imaging of the specific resist layer (remove the resist layer having the resist top loss defect and recoat the wafer to redo the imaging of the specific layer) before the irreversible processing (e.g., etching) is done.

In process P412, processing parameters under which the hot spots are processed (e.g., imaged or etched onto a substrate) are determined. The processing parameters may be local-dependent on the locations of the hot spots, the dies, or both. The processing parameters may be global—independent of the locations of the hot spots and the dies. One exemplary way to determine the processing parameters is to determine the status of the lithographic apparatus. For example, laser bandwidth, focus, dose, source parameters, projection optics parameters, and the spatial or temporal variations of these parameters, may be measured from the lithographic apparatus. Another exemplary way is to infer the processing parameters from data obtained from metrology performed on the substrate, or from operator of the processing apparatus. For example, metrology may include inspecting a substrate using a diffractive tool (e.g., ASML YieldStar), an electron microscope, or other suitable inspection tools. It is possible to obtain processing parameters for any location on a processed substrate, including the identified hot spots. The processing parameters may be compiled into a map—lithographic parameters, or process conditions, as a function of location. Of course, other processing parameters may be represented as functions of location, i.e., a map. In an embodiment, the processing parameters may be determined before, and preferably immediately before processing each hotspot.

In process P413, existence, probability of existence, characteristics, or a combination thereof, of a defect at a hot spot is determined using the processing parameters under which the hot spot is processed. This determination may be simply comparing the processing parameters and the process window of the hot spot—if the processing parameters fall within the process window, no defect exists; if the processing parameters fall outside the process window, at least one defect will be expected to exist. This determination may also be done using a suitable empirical model (including a statistical model). For example, a classification model may be used to provide a probability of existence of a defect. Another way to make this determination is to use a computational model to simulate an image or expected patterning contours of the hot spot under the processing parameters and measure the image or contour parameters. In an embodiment, the processing parameters may be determined immediately (i.e., before processing the pattern or the next substrate) after processing a pattern or a substrate. The determined existence and/or characteristics of a defect may serve as a basis for a decision of disposition: rework or acceptance. In an embodiment, the processing parameters may be used to calculate moving averages of the lithographic parameters. Moving averages are useful to capture long term drifts of the lithographic parameters, without distraction by short term fluctuations.

In an embodiment, hot spots are detected based on the simulated image of pattern on a substrate. Once the simulation of the patterning process (e.g., including process models such OPC and manufacturability check) is complete, potential weak points, i.e., hot spots, in the design as a function of process conditions may be computed according to one or more definitions (e.g., certain rules, thresholds, or metrics). Hot spots may be determined based on absolute CD values, on the rate of change of CD vs. one or more of the parameters that were varied in the simulation (“CD sensitivity”), on the slope of the aerial image intensity, or on NILS (i.e., “edge slope,” or “normalized image log slope,” often abbreviated as “NILS.” Indicating lack of sharpness or image blur) where the edge of the resist feature is expected (computed from a simple threshold/bias model or a more complete resist model). Alternatively, hot spots may be determined based on a set of predetermined rules such as those used in a design rule checking system, including, but not limited to, line-end pullback, corner rounding, proximity to neighboring features, pattern necking or pinching, and other metrics of pattern deformation relative to the desired pattern. The CD sensitivity to small changes in mask CD is a particularly important lithographic parameter known as MEF (Mask Error Factor) or MEEF (Mask Error Enhancement Factor). Computation of MEF vs. focus and exposure provides a critical metric of the probability that mask process variation convolved with wafer process variation will result in unacceptable pattern degradation of a particular pattern element. Hot spots can also be identified based on variation in overlay errors relative to underlying or subsequent process layers and CD variation or by sensitivity to variations in overlay and/or CD between exposures in a multiple-exposure process.

As semiconductor manufacturing advances to next technology nodes (e.g., single digit nm node), design patterns are used to drive improvements in process accuracy, stability and predictability. Manufacturing facilities are always looking for ways to improve their cycle time for manufacturing ICs. In the early stages of the development cycle, full-chip designs at the new node do not exist, although standard cell libraries and very small cell blocks will exist. To increase their pattern coverage, manufacturers create their own mock-up patterns via design shrink or some custom pattern creation method. After the first pass of model and a patterning process recipe generation, an early understanding of hotspot and non-hotspot patterns can be formed. Such patterns are valuable to drive improvements to simulation models, design rules, OPC, and verification recipes, and source illumination and mask optimization. Eventually, manufacturers will have a pattern set that is much more representative of the desired pattern or design layout, but it can take years to get to that point.

The manufacturers do not have enough pattern information in early process development cycles which impedes their ability to more quickly increase their rate of learning and development.

Today's methods for generating patterns shortly after the advent of a new technology node result in many unrealistic patterns versus what would eventually be encountered on a real substrate when printed. New patterns generated via existing methods cannot be instructed to generate only hotspot patterns or non-hotspot patterns which result in unfavorable software processing overhead (e.g., in terms of time, memory, resources, etc.) to properly assert newly created patterns.

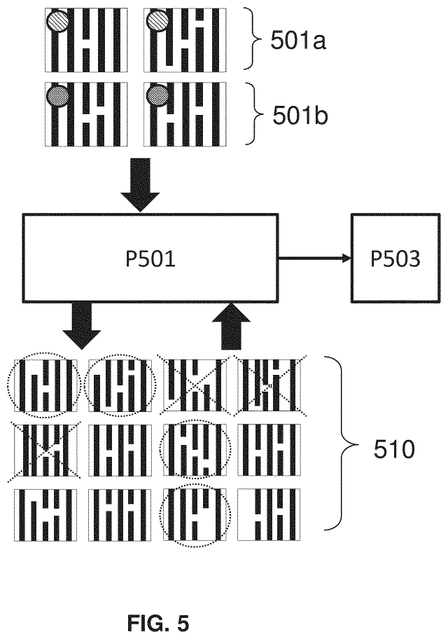

FIG. 5 is an illustration providing an overview of machine learning based characteristic pattern (e.g., hot spot pattern) generation method described herein. According to the methods of the present disclosure, a generator model is trained to generate a characteristic pattern such as a hot spot pattern, discriminate whether the characteristic pattern is a hot spot pattern or a non-hot spot pattern, and further validate the characteristic pattern with respect to design rule checks (DRC). The characteristic pattern is validated (e.g., as a hot spot pattern) and is stored in the hot spot database. The hot spot patterns can be used for different purposes during early stages of the patterning process, particularly, for mask layout design and determining optimum settings of apparatus(es) of the patterning process.

In an embodiment, a training set including hot spot patterns 501a and non-hot spot patterns 501b may be obtained for initial training of the machine learning model comprising a generator model and a discriminator model, discussed in more details later in the disclosure. The training set may be provided in a GDS format as a feature vector. In an embodiment, labels (e.g., hot spot, non-hot spot, etc.) may also be included in the training set.

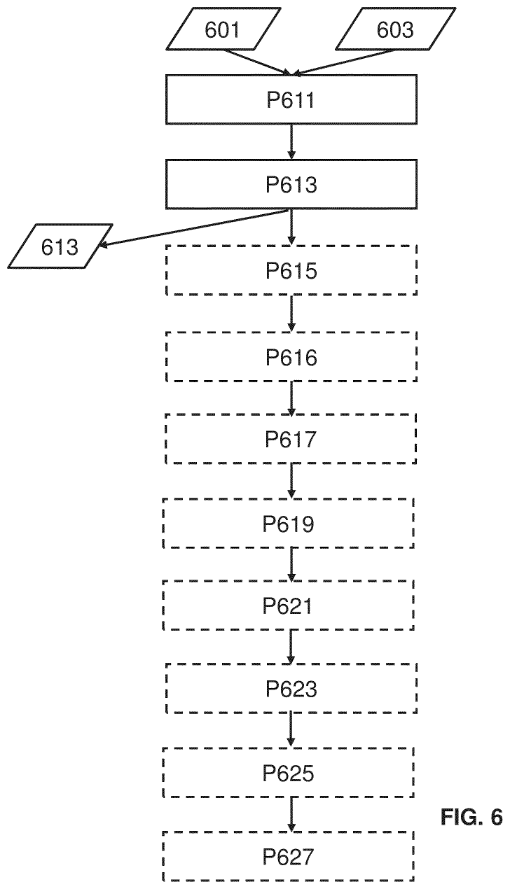

The training set with patterns 501a and 501b are input to the machine learning model in process P501. The process P501 involves training of the generator model and the discriminator model, discussed in detail with respect to FIG. 6. During the training process, a plurality of characteristic patterns may be generated by the generator model. Then, the discriminator model may identify a subset of these characteristic patterns as hot spots patterns, another subset as non-hot spot pattern, and yet another subset may be other patterns to be ignored. In addition, the process P501 involves performing DRC rule checks on the subset (e.g., a subset of hot spot patterns) of the characteristic patterns. Within the subset, only certain patterns may satisfy the DRC (e.g., patterns within 510 marked with circle), while some patterns fail the check (e.g., patterns within 510 marked with cross). While some other pattern may be ignored, as they do not qualify as either a hot spot pattern or a non-hot spot pattern.

The subset of characteristic patterns that are identified as the hot spot pattern as well as that satisfy the DRC may be stored in a database in process P503. Thus, a hot spot pattern database is created which can be used for various applications in the patterning process.

FIG. 6 is a flow chart of a method of generating a characteristic pattern for a patterning process. The method involves generating a characteristic pattern (e.g., a hot spot pattern) used for early design and development of design patterns, mask patterns, and/or determining setting (e.g., optimum values of dose, focus, etc.) of one or more apparatus used in the patterning process or values of different parameters of the patterning process. In an embodiment, a plurality of characteristic patterns may be generated using a trained generator model configured to generate a characteristic pattern (e.g., a mask layout). Such characteristic pattern, for example, a hot spot pattern or a set of hot spot patterns, are critical for setting up the patterning process, for example, when a new technology node (e.g., less than 10 nm) is defined or a new more complex design layout is defined. In an embodiment, the characteristic pattern and the input pattern may be represented as a pixelated image, a vector representing intensities of each pixel of the pixelated image, or other image related formats used in an image processing.

The method, in process P611, involves obtaining a trained generator model 601 configured to generate a characteristic pattern, and an input pattern 603.

In an embodiment, the characteristic pattern is any patterning device pattern (e.g., mask pattern) that can be used for designing patterns on substrate for a new technology node. In an embodiment, the characteristic pattern is a predicted pattern that may be potentially printed on a substrate subjected to the patterning process. The predict pattern may be determined (e.g., via simulation) based on, for example, shrinkage of a design layout. In an embodiment, the characteristic pattern may be one or more hot spot patterns or pattern similar to a hot spot pattern that were previously printed on a substrate subjected to a patterning process. In an embodiment, the characteristic pattern may be one or more patterns geometrically distinct from a hot spot pattern. In an embodiment, the characteristic pattern may be a pattern that satisfies design rule checks, and/or lithographic manufacturability checks.

A trained generator model 601 is be a machine learning model trained to generate a characteristic pattern. The training may be based on a training set comprising a sample (or a plurality of samples) of a hot spot pattern and/or labels indicating whether the characteristic pattern is a hot spot or non-hot spot pattern. The trained generator model 601 may also be trained to label the generated pattern (i.e., the characteristic pattern). The label may indicate whether the generated model is a hot spot pattern, not a hot spot pattern, a user-defined pattern, or other patterns types of interest (e.g., patterns with highest density, frequency of occurrence, metrology patterns).

In embodiment, the trained generator model 601 is a convolution neural network (CNN). The convolution neural network is constrained, for example, in terms of values of the weights and biases, number of layers, cost function, and other model parameters modified during training of the CNN. Thus, the CNN is a specific model trained based on a particular training data set comprising, for example, a hot spot pattern. Depending on a training method the trained generator model 601 may have different structure, weights, biases, etc. An example training method for training a machine learning model (e.g., CNN) is discussed with respect to FIG. 6. In an embodiment, the trained generator model 601 is trained according to a training method called a generative adversarial network. Training based on the generative adversarial network comprises two machine learning model trained together such that a generator model progressively generates more accurate and robust results.

In an embodiment, the trained generator model 601 can take for example, a design layout with hot spot, or a random vector, as input and generate a pattern in a form of pixelated images represented in, for example, GDS format.

The input pattern 603 may be a random vector, a pattern of a particular class of pattern (e.g., contact holes, bars, or a combination thereof), a design layout, and/or a shrunken version of a prior design layout (e.g., obtained by scaling down one or more features of the prior design layout. In an embodiment, the input pattern may be obtained via simulation of a process model of the patterning process with the design layout as an input that results in the hotspot pattern. Thus, based on a pattern type of interest, the trained generator model may predict a corresponding characteristic pattern. In an embodiment, the input pattern may be any input indicating a class of pattern for which a hot spot pattern may be generated.

Further, the method, in process P613, involves generating, via simulation of the trained generator model, the characteristic pattern 613 based on the input pattern. In an embodiment, the input pattern is a design layout including a hotspot pattern. In an embodiment, the characteristic pattern 613 corresponds to a hot spot pattern. In an embodiment, the characteristic pattern and the related input pattern may be stored in a hot spot pattern database.

In another embodiment, the characteristic pattern may be further modified, verified and validated, as discussed below, to ensure that the characteristic pattern satisfies the design specification when subjected to the patterning process. The validation may be based on simulation of the patterning process using the characteristic model. The result of the simulation the patterning process can be a simulated pattern that may be printed on the substrate. The results of the simulation may be verified with respect to design rule checks and/or manufacturability rule checks. The following process discusses additional steps of the method.

In an embodiment, the method, in process P615, includes converting the characteristic pattern to a characteristic contour representation. The characteristic contour representation refer to contours (i.e., outline or geometric shapes) of the patterns within the characteristic pattern. The converting of the characteristic pattern to contours representation includes extracting contours of features within the characteristic pattern. The contours can be extracted, for example, based on image processing configured to identify edges of a pattern or a shape in general. Once, the edges are extracted, the contours can be converted to geometric shapes (e.g., in GDS format) for further analysis such as design rule check.

In an embodiment, in process P616, before analyzing the contours or geometric shapes, a pre-processing on a free-form contours (e.g., curvilinear patterns) may performed. For example, the pre-processing may involve regularizing the contour representation to “Manhattanize” the free-form contour such that only horizontally and vertically running segments are obtained in converted polygons.

The analysis of the geometric shape or the characteristic contour representation (e.g., Manhattanized polygons), in process P617, involves applying a design rule check to the characteristic contour representation. The design rule checks may be an algorithm including conditional statements (e.g., if-then conditions) that defines whether the characteristic pattern may be printed within the design specification. For example, the design rule checks may be based on geometric shapes and dimensions. In an embodiment, a portion of the characteristic pattern (or contour) may not satisfy the design rule checks. In other words, the portion of the characteristic pattern that may be printed with defects or errors is identified.

For portions of the pattern that do not satisfy the design rule checks may be modified. For example, modifying the characteristic contour representation based on the design rule check to increase a likelihood that the characteristic pattern are printable, in process P619. For example, the modification may be involves increasing and/or decreasing a CD of a feature within the characteristic pattern. The amount of the modification may be predetermined rules or based on simulation of patterning process.

In an embodiment, an optical proximity corrections (OPC) may be applied to the characteristic pattern. For example, process P621 involves determining via simulation of the optical proximity correction model, optical proximity corrections for the modified characteristic contour.

Further, the modified characteristic pattern with OPC may be passed through the simulation process of the patterning process. For example, in process P623, includes determining, via simulation of the process model (e.g., as discussed earlier) of the patterning process, a simulated pattern of the substrate corresponding to the modified characteristic contour. The simulated pattern may be used to verify and validate the modified characteristic pattern. The validation may be based on comparison of defect data obtained from printed substrates corresponding to patterns similar to the characteristic pattern. The verification can indicate whether the characteristic pattern corresponds to hot spot patterns or not.

The above method has several applications. For example, the characteristic pattern (or the modified characteristic pattern) obtained above can be used for determining, via simulation of the process model of the patterning process, settings of the patterning process based on the characteristic pattern and/or the modified characteristic contour, in process P625. The settings of the patterning process may involve optimization of parameters of the patterning process. In an embodiment, the settings of the patterning process are values of the process variables including dose, focus, and/or optical parameters.

The settings determined based on the characteristic pattern may be further used for printing, via the lithographic apparatus, the characteristic pattern on the substrate, in process P627.

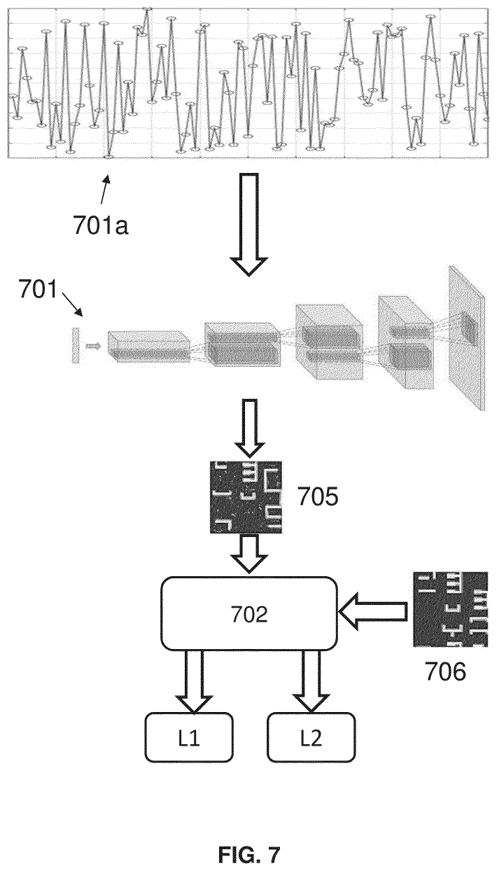

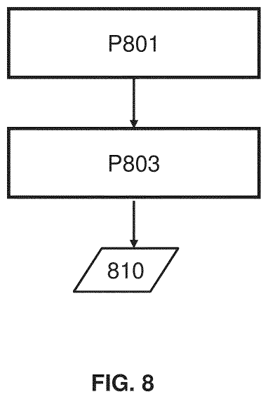

FIG. 7 illustrates an overview of a training process of a machine learning model based on generative adversarial network architecture. In an embodiment, a generator model 701 receives an input pattern 701a in the form of a pixelated image or a vector. In an embodiment, the input pattern 701a is a 100 dimensional vector, each element having a real value between 0 and 1. The generator model 701 is a convolution neural network with multiple layers, as illustrated. Each layer may have particular stride length and a specific kernel. The last layer of the generator model 701 outputs a characteristic pattern 705 (also referred as a fake pattern 705). The characteristic pattern 705 is received by a discriminator model 702, which is another CNN. The discriminator model 702 also receives a real pattern 706 (or a set of real patterns) in the form of a pixelated image. Based on the real pattern 706, the discriminator model determines whether the characteristic pattern is fake (e.g., label L1) or real (e.g., label L2) and assigns labels accordingly. The set of real patterns can be a set of clips of a printed wafer. Thus, the training of the model 702 is based on a plurality of real patterns. Accordingly, the training is based on a batch of real patterns, together with a batch of fake, generated patterns. FIG. 8 discussed the training method in more detail below.

In an embodiment, the input pattern 701 may be a seed hotspot image. The seed hotspot image may be obtained from simulation of lithographic process with one or more design layout as an input. The simulation may involve, for example, OPC simulation to determine a mask layout via OPC model and mask model simulation. Further, optical model, resist model, and manufacturability check simulation may be performed to obtain a simulated substrate pattern. The simulated pattern may be a hot spot pattern or a non-hot spot pattern that reveals whether a defect may appear on the substrate, if the OPC corrected design layout is subjected to the patterning process.

In an embodiment, a plurality of design layouts may be simulated and locations on the design layout where hot spots are observed may be selected as seed hot spot image.

FIG. 8 is a flow chart of a method of training a generator model discussed above for generating a characteristic pattern of a patterning process. The following training method is based on a generative adversarial network (GAN) that includes two machine learning model—a generator model (e.g., CNN) and a discriminator model (e.g., CNN), trained together, particularly in opposition to one another. The generator model can take as input a random vector (z) and output an image, which may be termed as a fake image. A fake image is an image of a certain class (e.g., a hot spot pattern) that never actually existed before. On the other hand, a real image refers to a previously existing image (e.g., hot spot pattern for a printed substrate) that may be used during the training of the generator model and the discriminator model. A real image may also be referred as a ground truth or a training pattern. The goal of the training is to train the generator model to generate fake images that closely resemble the real image. For example, the features of the fake image are at least 95% match with the features of the real image. Consequently, the trained generator model is capable of generating fake images (i.e., characteristic patterns) of a certain class (e.g., hot spot, non-hot spot, etc.) with high level of accuracy.

The training method, in process P801, involves obtaining a machine learning model including a generator model configured to generate a characteristic pattern and a discriminator model configured to distinguish the characteristic pattern from a training pattern. During the training, the generator model is not aware of what the training pattern (e.g., a hot spot pattern) i.e., a realistic pattern looks like. On the other hand, the discriminator model is aware of the training pattern. Thus, after the completion of the training process, the generator model is robust and can generate characteristic patterns for any type of pattern with high accuracy.

In an embodiment, the training pattern includes a hotspot pattern or a set of hot spot patterns obtained from previously printed substrate. In an embodiment, the training pattern may be generated via simulation of a process model of the patterning process (e.g., as discussed earlier), metrology data of a printed substrate, and/or a database storing printed patterns. The training pattern(s) may be associated with a label(s) such as hot spot. In an embodiment, the labels can be non-hot spot, pattern type 1, pattern type 2, real pattern, etc. The pattern type 1 and pattern type 2 refers to any user-defined patterns.

In an embodiment, the generator model (G) may be a convolution neural network. The generator model (G) takes as input a random noise vector z and generate an image. In an embodiment, the image may be referred as fake image or a characteristic image. The fake image can be expressed as X_{fake}=G(z). In an embodiment, the generator model may be augmented with supplementary information such as labels during the training process. Consequently, the trained generator model can generate characteristic images of a particular label (e.g., hot spot pattern) as desired by the user.

The generator model (G) may be associated with a first cost function. The first cost function enables tuning of parameters of the generator model such that the cost function is improved (e.g., maximized or minimized). In an embodiment, the first cost function comprises a first log-likelihood term that determines a probability that the characteristic pattern is a fake image given the input vector.

An example of the first cost function can be expressed by equation 1 below:

Lₛ=E[log P(S=fake|X_{fake})] (1)

In above equation 1, a log likelihood of conditional probability is computed. In the equation, S refers to a source assignment as fake by the discriminator model and X_{fake} is an output i.e., a fake image of the generator model. Thus, in an embodiment, the training method minimizes the first cost function (L). Consequently, the generator model will generate fake images (i.e., the characteristic images) such that the conditional probability that the discriminator model will realize the fake image as fake is low. In other words, the generator model will progressively generate more and more realistic images or patterns.

In another example, the generator model may be configured to generate images based on a particular class. In this case, the first cost function (in eq. 1) may include an additional terms related to probability of a class c as follows:

L_{c}=E[log P(C=c|X_{fake})] (2)

The equation 2 above, indicates the log likelihood that the generator model generates an image of a particular class c. In an embodiment, the label c may be a hot spot pattern or a non-hot spot pattern. In an embodiment, the L_{c} may be maximized, for example, to maximize the probability of generating a hot spot pattern.

In an embodiment, the discriminator model (D) may be a convolution neural networks. The discriminator model (D) receives as input—a real image and the fake image, and outputs a probability that the input is a fake image or a real image. The probability can be expressed as P(S|X)=D(X). In other words, if the fake image generated by the generator model is not good (i.e., close to a real image), then the discriminator model will output a low probability value (e.g., less than 50%) to the input image. This indicates the input image is a fake image. As the training progresses, the generator model produces images closely resembling a real image, thus, eventually the discriminator model may not be able to distinguish whether the input image is a fake image or a real image.

In an embodiment, the discriminator model may be associated with a second cost function. The second cost function enables tuning of the parameters of the discriminator model such that the cost function is improved (e.g., maximized). In an embodiment, the second cost function includes a second log-likelihood term that determines a conditional probability that the fake pattern (i.e., a characteristic pattern) is real given the training pattern. A probabilistic comparison between the fake patterns to the training pattern(s), allows the discriminator model to progressively get better at identifying a fake image from the real image.

An example of the second cost function can be expressed by equation 3 below:

Lₛ=E[log P(S=real|Xᵣₑₐₗ)]+E[log P(S=fake|X_{fake})] (3)

In above equation, a log likelihood of conditional probability is computed. In the equation, S refers to a source assignment as real given that the input is a real image Xᵣₑₐₗ, and a source assignment as fake given that the input image is a fake image X_{fake} i.e., a fake image of the generator model. In an embodiment, the training method maximizes the second cost function (eq. 3). Consequently, the discriminator model progressively gets better at distinguishing a real image from a fake image.

In another example, the discriminator model may be configured to assign labels to images based on a particular class. In this case, the second cost function (in eq. 3) may include an additional terms related to probability of a class c as follows:

L_{c}=E[log P(C=c|Xᵣₑₐₗ)]+E[log P(C=c|X_{fake})] (4)

The equation 4 above, indicates the log likelihood that the discriminator model assigns an image of a particular class c (e.g., a hot spot or a non-hot spot).

Thus, the generator model and the discriminator model are trained simultaneously, such that the discriminator model provides a feedback to the generator model about quality of the fake image (i.e., how closely the fake image resembles the real image). Further, the quality of the fake image gets better, the discriminator model needs to get better at distinguishing the fake image from the real image. The goal is to train the models till they do not improve each other. For example, the improvement may be indicated by the values of respective cost functions which do not change substantially over further iterations.

Further, process P803 involves training the generator model and the discriminator model in a cooperative manner (for example, in tandem) based on a training set comprising the training pattern, such that the generator model generates the characteristic pattern that matches the training pattern and the discriminator model identifies the characteristic pattern as the training pattern. In other words, the generator model is trained in cooperation with discriminator model and vice-versa, so that output of one model improves the other model or the predictions therefrom.

The training is an iterative process, where an iteration includes generating the characteristic pattern, via simulation of the generator model with an input vector and evaluating the first cost function (e.g., eq. 1 or eq. 2 discussed above). In an embodiment, the input vector may be n-dimensional random vector (e.g., a 100 dimension vector, a 100×100 dimension vector), where each element of the vector is randomly assigned value. For example, each element of the input vector can have a certain value or a random value between 0 and 1, for example, representing a probability value. For example, the input vector can be [0, 0.01, 0.05, 0.5, 0.6, 0.02 . . . ]. In an embodiment, the random values may be randomly selected from a Gaussian probability distribution.

In an embodiment, the input vector may be a seed hotspot image. The seed hotspot image may be obtained from simulation of lithographic process with one or more design layout as an input, as discussed earlier with respect to process P611.

In an embodiment, the generator model generates the characteristic pattern includes features resembling the training pattern. In an embodiment, the characteristic pattern and the training pattern may include a non-hotspot pattern, and/or a user-defined pattern.

Further, in the iteration within the process P803, the characteristic pattern is received by the discriminator model for distinguishing the characteristic pattern from a corresponding realistic pattern or the training pattern and evaluate the second cost function. The discriminator model is aware of the real pattern, as it is one of the inputs to the discriminator model for training purposes.

In an embodiment, the distinguishing involves determining a probability that the characteristic pattern is the training pattern. For example, using equations 3 or 4 where the real pattern is given and fake pattern is received as the characteristic pattern from the generator model. In response to the probability value, a label is assigned to the characteristic pattern. The label indicates whether the characteristic pattern is as a real pattern or a fake pattern.

In an embodiment, responsive to the probability breaching a threshold value (e.g., greater than 90%), the characteristic pattern is labelled as a real pattern.

Further, the training involves adjusting parameters of the generator model to improve the first cost function, and parameters of the discriminator model to improve the second cost function. In an embodiment, adjusting of the parameter may be based on a technique that involves a back-propagation thorough various layers of the machine learning model for updating the model parameters. In an embodiment, a gradient of the cost function may be computed during the back propagation and weights and biases of different layers may be adjusted based on the gradient, for example, to reduce (or minimize) the cost function.

In an embodiment, the first cost function may be reduced (or minimized) so that the generator model produces fake images to closely resemble the real image, as discussed earlier with respect to equations 1 and 2. Similarly, the second cost function may be increased (or maximized) so that the discriminator model can better distinguish between the fake image and the real image, as discussed earlier with respect to equations 1 and 2.

After several iterations of the training process, the generator model and the discriminator model converge. In other words, adjustments to the parameters of the respective models do not improve the respective cost functions. Thus, the generator model is considered as a trained generator model 810 (an example of trained generator model 601). Now, the trained generator model 810 can be used to directly determine a characteristic pattern based on, for example, a seeded hot spot image corresponding to a design layout. Effectively, generating, via simulation of the trained generator model, a design pattern including a hotspot pattern and/or a user-defined pattern.

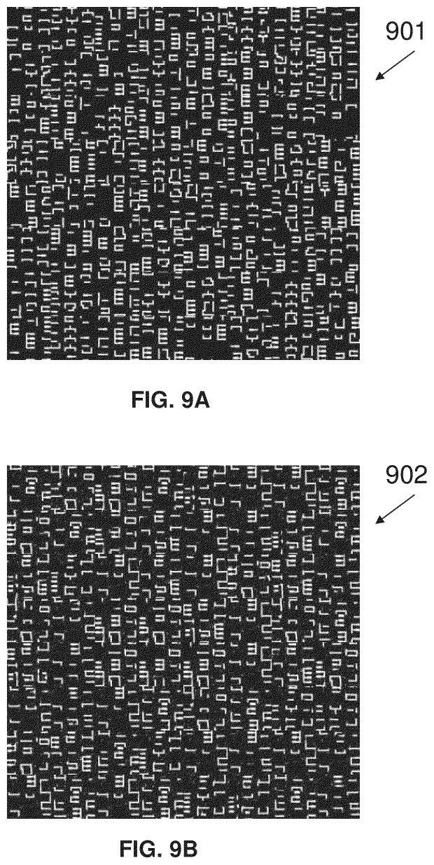

FIG. 9A is an example of a real pattern 901 and 9B is an example of a characteristic pattern 902 generated by the trained generator model (e.g., 603 or 910). The characteristic pattern 902 includes features that are substantially similar to features of the real pattern 901. Thus, the trained generator model (e.g., 603 or 910) generates patterns that may match the real pattern. In an embodiment, several features within the characteristic pattern may not exactly match (e.g., in terms of shape, size, location, orientation, etc.) with corresponding features within the real pattern.

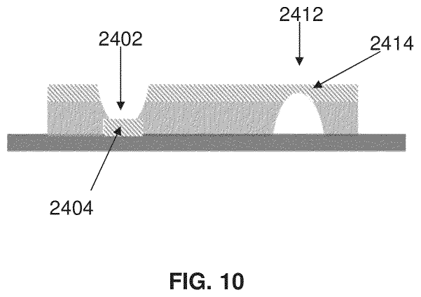

FIG. 10 illustrates example defects and example ways to tackle the defects. For example, as shown in FIG. 10, a footing 2402 and necking 2412 type of failure may be observed for certain setting of the process variable such as dose/focus. In case of footing, de-scumming may be performed to remove a foot 2404 at the substrate. In case of the necking 2412, a resist thickness may be reduced by removing a top layer 2414. Thus, defect-based process window may be improved at an expense of resist. In embodiment, modelling/simulation may be performed to determine an optimum thickness without changing/compromising the process window (i.e., having a desired yield), so less defects (e.g., necking/footing) may be observed.

According to an embodiment, there is provided a method of generating a characteristic pattern for a patterning process. The method includes obtaining a trained generator model configured to generate a characteristic pattern, and an input pattern; and generating, via simulation of the trained generator model, the characteristic pattern based on the input pattern, wherein the input pattern is at least one of a random vector or a class of pattern.

In an embodiment, the characteristic pattern is a patterning device pattern to be printed on a substrate subjected to the patterning process.

In an embodiment, the input pattern is obtained via simulation of a process model of the patterning process with a design layout as an input that results in the hotspot pattern.

In an embodiment, the process model comprises an optical proximity correction model and a lithographic manufacturability check model.

In an embodiment, the method further includes converting the characteristic pattern to a characteristic contour representation; applying a design rule check to the characteristic contour representation; and modifying the characteristic contour representation based on the design rule check to increase a likelihood that the characteristic pattern are printable.

In an embodiment, the converting the characteristic pattern comprises extracting contours of features within the characteristic pattern; and converting the contours to geometric shapes and/or Manhattanize the characteristic pattern.

In an embodiment, the method further comprising: determining via simulation of the optical proximity correction model, optical proximity corrections for the modified characteristic contour; determining, via simulation of the process model of the patterning process, a simulated pattern of the substrate corresponding to the modified characteristic contour.

In an embodiment, the method further comprising: determining, via simulation of the process model of the patterning process, settings of the patterning process based on the characteristic pattern and/or the modified characteristic contour.

In an embodiment, the settings of the patterning process are values of the process variables including dose, focus, and/or optical parameters.

In an embodiment, the method further comprising: printing, via the lithographic apparatus, the characteristic pattern on the substrate applying the settings of the patterning process.

In an embodiment, the trained generator model is a convolution neural network.

In an embodiment, the trained generator model is trained according to a machine learning training method called a generative adversarial network.

In an embodiment, the characteristic pattern and the input pattern is a pixelated image.

In an embodiment, the input pattern includes a design layout including a hotspot pattern.

Furthermore, the present disclosure provides a method of training a machine learning model for generating a characteristic pattern of a patterning process. The method includes obtaining a machine learning model comprising (i) a generator model configured to generate a characteristic pattern to be printed on a substrate subjected a patterning process, and (ii) a discriminator model configured to distinguish the characteristic pattern from a training pattern; and training, via a computer hardware system, the generator model and the discriminator model in a cooperative manner other based on a training set comprising the training pattern, such that the generator model generates the characteristic pattern that matches the training pattern and the discriminator model identifies the characteristic pattern as the training pattern, wherein the characteristic pattern and the training pattern comprises a hotspot pattern.

In an embodiment, the training is an iterative process, an iteration comprises: generating the characteristic pattern, via simulation of the generator model with an input vector; evaluating a first cost function related to the generator model; distinguishing, via the discriminator model, the characteristic pattern from the training pattern; evaluating a second cost function related to the discriminator model; and adjusting parameters of the generator model to improve the first cost function, and parameters of the discriminator model to improve the second cost function.

In an embodiment, the input vector is a random vector and/or a seed hotspot image.

In an embodiment, the seed hotspot image is obtained from simulation of lithographic process with a design layout as an input.

In an embodiment, the distinguishing comprises: determining a probability that the characteristic pattern is the training pattern; and responsive to the probability, assigning a label to the characteristic pattern, the label indicates whether the characteristic pattern is as a real pattern or a fake pattern.

In an embodiment, responsive to the probability breaching a threshold value, the characteristic pattern is labelled as a real pattern.

In an embodiment, the first cost function comprises a first log-likelihood term that determines a probability that the characteristic pattern is a fake given the input vector.

In an embodiment, the adjusting of parameters of the generator model is such that the first log-likelihood term is minimized.

In an embodiment, the second cost function includes a second log-likelihood term that determines a probability that the characteristic pattern is real given the training pattern.

In an embodiment, the adjusting of the second model parameters is such that the second log-likelihood term is maximized.

In an embodiment, the training pattern includes a hotspot pattern.

In an embodiment, the training pattern is obtained from simulation of a process model of the patterning process, metrology data of a printed substrate, and/or a database storing printed patterns.

In an embodiment, the characteristic pattern includes features resembling the training pattern;

In an embodiment, the characteristic pattern and the training pattern further comprises a non-hotspot pattern, and/or a user-defined pattern.

In an embodiment, the method further comprising generating, via simulation of the trained generator model, a design pattern including a hotspot pattern and/or a user-defined pattern.

In an embodiment, the generator model and the discriminator model are convolution neural networks.

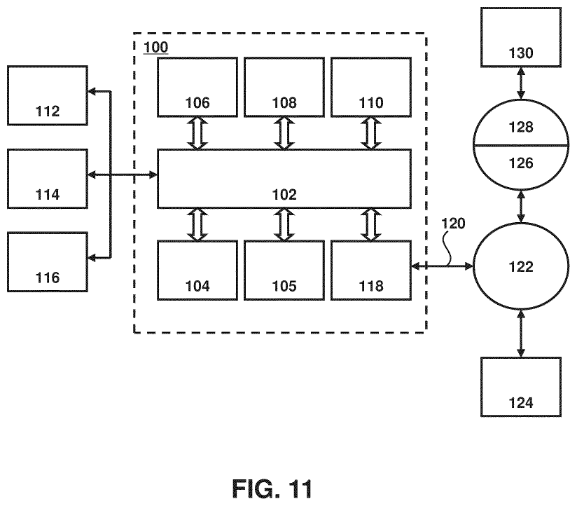

FIG. 11 is a block diagram that illustrates a computer system 100 which can assist in implementing the methods, flows or the apparatus disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide all or part of a method described herein, for example. The received code may be executed by processor 104 as it is received, and/or stored in storage device 110, or other non-volatile storage for later execution. In this manner, computer system 100 may obtain application code in the form of a carrier wave.

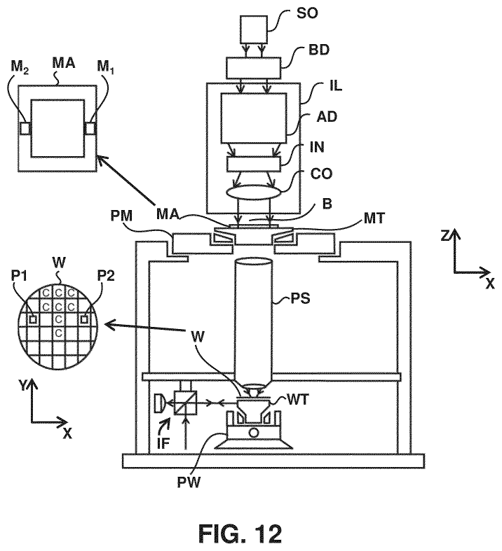

FIG. 12 schematically depicts an exemplary lithographic projection apparatus in conjunction with the techniques described herein can be utilized. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 12 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 12. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

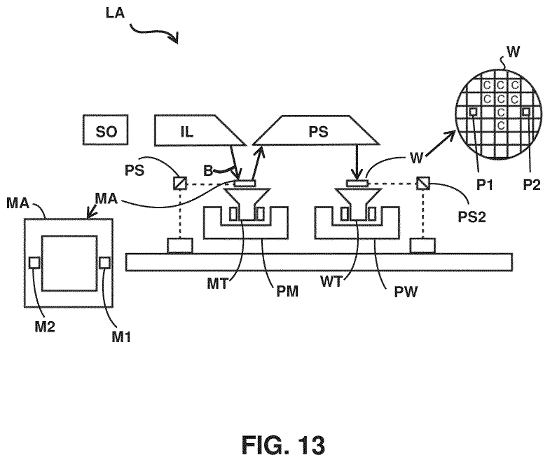

FIG. 13 schematically depicts another exemplary lithographic projection apparatus 1000 in conjunction with the techniques described herein can be utilized.

The lithographic projection apparatus 1000 comprises:
a source collector module SO
an illumination system (illuminator) IL configured to condition a radiation beam B (e.g. EUV radiation).
a support structure (e.g. a patterning device table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective patterning device). It is to be noted that because most materials are absorptive within the EUV wavelength range, the patterning device may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 13, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 13, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the source may be an integral part of the source collector module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:

1. In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the support structure (e.g. patterning device table) MT and the substrate table WT are scanned synchronously while a pattern imparted to the radiation beam is projected onto a target portion C (i.e. a single dynamic exposure). The velocity and direction of the substrate table WT relative to the support structure (e.g. patterning device table) MT may be determined by the (de-)magnification and image reversal characteristics of the projection system PS.

3. In another mode, the support structure (e.g. patterning device table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

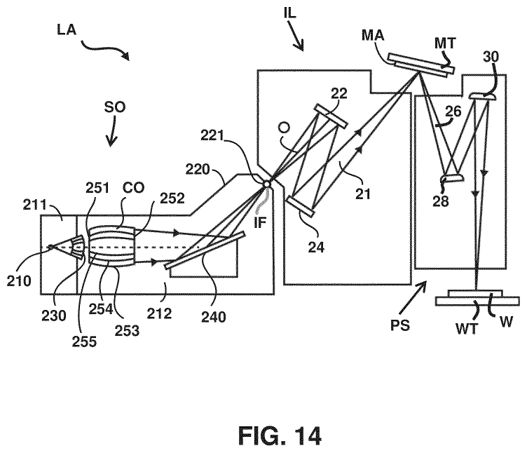

FIG. 14 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 14.

Collector optic CO, as illustrated in FIG. 14, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

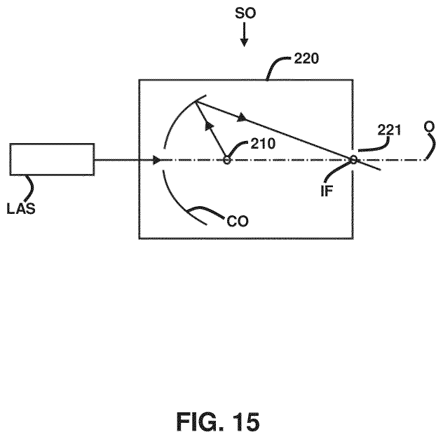

Alternatively, the source collector module SO may be part of an LPP radiation system as shown in FIG. 15. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The embodiments may further be described using the following clauses:

1. A method of generating a characteristic pattern for a patterning process, the method comprising:
obtaining a trained generator model configured to generate a characteristic pattern, and an input pattern; and
generating, via simulation of the trained generator model, the characteristic pattern based on the input pattern, wherein the input pattern is at least one of a random vector or a class of pattern.
2. The method clause 1, wherein the characteristic pattern is a patterning device pattern to be printed on a substrate subjected to the patterning process.
3. The method of any of clauses 1-2, wherein the input pattern is obtained via simulation of a process model of the patterning process with a design layout as an input that results in the hotspot pattern.
4. The method of any of clause 3, wherein the process model comprises an optical proximity correction model and a lithographic manufacturability check model.
5. The method of any of clauses 1-4, further comprising:
converting the characteristic pattern to a characteristic contour representation;
applying a design rule check to the characteristic contour representation; and
modifying the characteristic contour representation based on the design rule check to increase a likelihood that the characteristic pattern are printable.
6. The method of clause 5, wherein the converting the characteristic pattern comprises:
extracting contours of features within the characteristic pattern; and
converting the contours to geometric shapes and/or Manhattanize the characteristic pattern.
7. The method of any of clauses 4-6, further comprising:
determining via simulation of the optical proximity correction model, optical proximity corrections for the modified characteristic contour;
determining, via simulation of the process model of the patterning process, a simulated pattern of the substrate corresponding to the modified characteristic contour.
8. The method of any of clauses 1-7, further comprising:
determining, via simulation of the process model of the patterning process, settings of the patterning process based on the characteristic pattern and/or the modified characteristic contour.
9. The method of clause 8, wherein the settings of the patterning process are values of the process variables including dose, focus, and/or optical parameters.
10. The method of any of clauses 8-9, further comprising:
printing, via the lithographic apparatus, the characteristic pattern on the substrate applying the settings of the patterning process.
11. The method of any of clauses 1-10, wherein the trained generator model is a convolution neural network.
12. The method of any of clauses 1-11, wherein the trained generator model is trained according to a machine learning training method called a generative adversarial network.
13. The method of any of clauses 1-12, wherein the characteristic pattern and the input pattern is a pixelated image.
14. The method of any of clauses 1-3, wherein the input pattern includes a design layout including a hotspot pattern.
15. A method of training a machine learning model for generating a characteristic pattern of a patterning process, the method comprising:
obtaining a machine learning model comprising (i) a generator model configured to generate a characteristic pattern to be printed on a substrate subjected a patterning process, and (ii) a discriminator model configured to distinguish the characteristic pattern from a training pattern; and

training, via a computer hardware system, the generator model and the discriminator model in a cooperative manner other based on a training set comprising the training pattern, such that the generator model generates the characteristic pattern that matches the training pattern and the discriminator model identifies the characteristic pattern as the training pattern,

wherein the characteristic pattern and the training pattern comprises a hotspot pattern.
16. The method of clause 15, wherein the training is an iterative process, an iteration comprises:
generating the characteristic pattern, via simulation of the generator model with an input vector;
evaluating a first cost function related to the generator model;
distinguishing, via the discriminator model, the characteristic pattern from the training pattern;
evaluating a second cost function related to the discriminator model; and
adjusting parameters of the generator model to improve the first cost function, and parameters of the discriminator model to improve the second cost function.
17. The method of any of clauses 15-16, wherein the input vector is a random vector and/or a seed hotspot image.
18. The method of clause 17, wherein the seed hotspot image is obtained from simulation of lithographic process with a design layout as an input.
19. The method of any of clauses 16-18, wherein the distinguishing comprises:
determining a probability that the characteristic pattern is the training pattern; and
responsive to the probability, assigning a label to the characteristic pattern, the label indicates whether the characteristic pattern is as a real pattern or a fake pattern.
20. The method of clause 19, wherein responsive to the probability breaching a threshold value, the characteristic pattern is labelled as a real pattern.
21. The method of any of clauses 16-20, wherein the first cost function comprises a first log-likelihood term that determines a probability that the characteristic pattern is a fake given the input vector.
22. The method of clause 21, wherein the adjusting of parameters of the generator model is such that the first log-likelihood term is minimized.
23. The method of any of clauses 16-22, wherein the second cost function includes a second log-likelihood term that determines a probability that the characteristic pattern is real given the training pattern.
24. The method of clause 23, wherein the adjusting of the second model parameters is such that the second log-likelihood term is maximized.
25. The method of any of clauses 15-23, the training pattern includes a hotspot pattern.
26. The method of any of clauses 15-25, the training pattern is obtained from simulation of a process model of the patterning process, metrology data of a printed substrate, and/or a database storing printed patterns.
27. The method of any of clauses 15-26, the characteristic pattern includes features resembling the training pattern;
28. The method of any of clauses 15-27, wherein the characteristic pattern and the training pattern further comprises a non-hotspot pattern, and/or a user-defined pattern.
29. The method of any of clauses 15-28, further comprising generating, via simulation of the trained generator model, a design pattern including a hotspot pattern and/or a user-defined pattern.
30. The method of any of clauses 14-29, wherein the generator model and the discriminator model are convolution neural networks.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A method comprising:
obtaining a machine learning model comprising (i) a generator model configured to generate a characteristic pattern to be printed on a substrate subjected to a patterning process, and (ii) a discriminator model configured to distinguish the characteristic pattern from a training pattern; and
training, by a computer hardware system, the generator model and the discriminator model in a cooperative manner based on a training set comprising the training pattern, such that the generator model generates the characteristic pattern that matches the training pattern and the discriminator model identifies the characteristic pattern as the training pattern,
wherein the characteristic pattern and the training pattern comprises a hotspot pattern.

2. The method of claim 1, wherein the training is an iterative process, an iteration comprises:
generating the characteristic pattern, via simulation using the generator model with an input vector;
evaluating a first cost function related to the generator model;
distinguishing, via the discriminator model, the characteristic pattern from the training pattern;
evaluating a second cost function related to the discriminator model; and
adjusting one or more parameters of the generator model to improve the first cost function, and one or more parameters of the discriminator model to improve the second cost function.

3. The method of claim 2, wherein the input vector is a random vector and/or a seed hotspot image.

4. The method of claim 3, wherein the input vector is a seed hotspot image and the seed hotspot image is obtained from simulation of a lithographic process with a design layout as an input.

5. The method of claim 2, wherein the distinguishing comprises:
determining a probability that the characteristic pattern is the training pattern; and
responsive to the probability, assigning a label to the characteristic pattern, the label indicating whether the characteristic pattern is a real pattern or a fake pattern.

6. The method of claim 2, wherein the first cost function comprises a log-likelihood term that determines a probability that the characteristic pattern is a fake given the input vector.

7. The method of claim 6, wherein the adjusting of one or more parameters of the generator model is such that the first log-likelihood term is minimized.

8. The method of claim 2, wherein the second cost function includes a log-likelihood term that determines a probability that the characteristic pattern is real given the training pattern.

9. The method of claim 1, wherein the training pattern includes a hotspot pattern.

10. The method of claim 1, wherein the training pattern is obtained from simulation using a process model of the patterning process, from metrology data of a printed substrate, and/or from a database storing printed patterns.

11. The method of claim 1, wherein the characteristic pattern includes features resembling the training pattern.

12. The method of claim 1, wherein the characteristic pattern and the training pattern further comprises a non-hotspot pattern, and/or a user-defined pattern.

13. The method of claim 1, further comprising generating, via simulation using the trained generator model, a design pattern including a hotspot pattern and/or a user-defined pattern.

14. The method of claim 1, wherein the generator model and the discriminator model are convolution neural networks.

15. A computer product comprising a non-transitory computer-readable medium having instructions therein, the instructions, upon execution by a computer system, configured to cause the computer system to at least:
obtain a machine learning model comprising (i) a generator model configured to generate a characteristic pattern to be printed on a substrate subjected to a patterning process, and (ii) a discriminator model configured to distinguish the characteristic pattern from a training pattern; and
train the generator model and the discriminator model in a cooperative manner based on a training set comprising the training pattern, such that the generator model generates the characteristic pattern that matches the training pattern and the discriminator model identifies the characteristic pattern as the training pattern,
wherein the characteristic pattern and the training pattern comprises a hotspot pattern.

16. The computer product of claim 15, wherein the training is an iterative process, an iteration comprising:
generation of the characteristic pattern, via simulation using the generator model with an input vector;
evaluation of a first cost function related to the generator model;
distinguishing, via the discriminator model, of the characteristic pattern from the training pattern;
evaluation of a second cost function related to the discriminator model; and
adjustment of one or more parameters of the generator model to improve the first cost function, and one or more parameters of the discriminator model to improve the second cost function.

17. The computer product of claim 16, wherein the input vector is a random vector and/or a seed hotspot image.

18. The computer product of claim 16, wherein the first cost function comprises a log-likelihood term that determines a probability that the characteristic pattern is a fake given the input vector.

19. The computer product of claim 16, wherein the second cost function includes a log-likelihood term that determines a probability that the characteristic pattern is real given the training pattern.

20. The computer product of claim 16, wherein the distinguishing comprises:
determination of a probability that the characteristic pattern is the training pattern; and
responsive to the probability, assignment of a label to the characteristic pattern, the label indicating whether the characteristic pattern is a real pattern or a fake pattern.
